(19) United States
(12) Patent Application Publication
(10) Pub. No.: US 2021/0391501 A1
(43) Pub. Date: Dec. 16, 2021

(54) MICRO LIGHT-EMITTING DIODE INCLUDING OPTIMIZED PASSIVATION LAYER AND METHOD OF FABRICATING THE SAME

(71) Applicant: Korea University Research and Business Foundation, Seoul (KR)

(72) Inventors: Tae Yeon SEONG, Seoul (KR); Da Hoon LEE, Seoul (KR)

(21) Appl. No.: 17/106,508

(22) Filed: Nov. 30, 2020

(30) Foreign Application Priority Data
Jun. 15, 2020 (KR) 10-2020-0072237

(51) Int. Cl. H01L 33/32; H01L 33/00

(52) U.S. Cl. CPC H01L 33/325; H01L 33/0095

(57) ABSTRACT

Disclosed is a group III-V compound-based micro light-emitting diode that includes an optimized passivation layer, and thus, is capable of reducing leakage current in a micro light-emitting diode. More particularly, the micro light-emitting diode includes a passivation layer that includes first and second passivation layers formed using different deposition methods, thereby being capable of efficiently reducing leakage current of sidewalls and thus improving the efficiency of a micro light-emitting diode.

### CROSS-REFERENCE TO RELATED APPLICATION

This application claims the priority benefit of Korean Patent Application No. 10-2020-0072237, filed on Jun. 15, 2020, in the Korean Intellectual Property Office, the disclosure of which is incorporated herein by reference.

### BACKGROUND OF THE DISCLOSURE

### Field of the Disclosure

The present disclosure relates to a micro light-emitting diode including an optimized passivation layer and a method of fabricating the same, and more particularly, to a group III-V compound-based micro light-emitting diode that includes an optimized passivation layer, and thus, is capable of reducing leakage current in a micro light-emitting diode and improving the efficiency thereof.

### Description of the Related Art

Despite the continuous development of current commercial display technologies such as Liquid Crystal Display (LCD) and Organic Light-Emitting Diode (OLED), it is necessary to further improve performance so as to meet the requirements for use as a next-generation display.

On the other hand, inorganic-based micro light-emitting diodes (micro-LEDs) have excellent characteristics such as fast response, low power consumption, outstanding resolution, and thermal stability, thereby having the potential for application to various fields such as wearable devices, large-area displays, visible light communication (VLC), micro display, and biomedicals.

In addition, since a micro light-emitting diode is a relatively new technology, research and development thereof have not been sufficiently progressed yet and optimization of a manufacturing process thereof has not been realized. Accordingly, a micro light-emitting diode has many problems (epitaxy and chip processing, assembly technologies, mass transfer technologies, etc.).

In addition, due to the excellent characteristics described above, a micro light-emitting diode is known to have great potential for use in the display fields and the biomedical application fields such as photogenetics and multi-site neuronal stimulation

However, for applications to displays, a light-emitting diode (LED) still has optimization problems regarding a micro light-emitting diode manufacturing process, the growth of a uniform epitaxial layer (having low defect density), improved light-emitting diode performance, mass transmission and packaging.

Unlike existing light-emitting diodes (>300 μm×300 μm), a micro light-emitting diode (<100 μm×100 μm) has a small chip size (i.e., a large ratio of volume to surface), which can lead to serious process problems. One of major challenges is related to Shockley-Read-Hall (SRH) non-radiative recombination, and a light-emitting diode according to a conventional technology may be induced by sidewall damage that occurs as a result of Inductively-Coupled-Plasma Reactive Ion Etching (ICP-RIE) for chip separation.

Due to increased sidewalls, a smaller light-emitting diode can produce higher SRH recombination.

However, despite the obstacles, a micro light-emitting diode (<10 μm×10 μm) is advantageous in terms of cost and resolution. Different types of sidewall passivation processes should be performed to improve defect-related recombination behavior of micropassives.

Plasma-Enhanced Chemical Vapor Deposition (PECVD) technology has been widely used as a tool for a sidewall passivation process.

Upon commercial production of GaN-based light-emitting diodes, PECVD technology exhibits a high deposition rate, but may cause sidewall damage due to plasma, which causes leakage current.

Meanwhile, Atomic Layer Deposition (ALD) technology has advantages, such as step coverage and precise layer thickness control, and can effectively suppress leakage current caused by sidewall defects.

The thickness of a dielectric layer deposited on a sidewall is relatively thin. compared to the thickness of a dielectric layer on a planar surface area.

Accordingly, a micro light-emitting diode may fail due to breakdown of a dielectric on a sidewall or opening of a dielectric film when a spot is thin.

In addition, a low deposition rate of ALD has a negative impact on formation (e.g., deposition) of a thick dielectric film. Accordingly, there is a need for a micro light-emitting diode including the above advantages, but excluding the above disadvantages, and a method of fabricating the same.

Sidewall issues may occur as a chip size is reduced. Sidewall damage may occur when the ICP-RIE process for chip isolation is performed, and a perimeter to area ratio may increase as a chip size is reduced.

This causes severe Shockley-Read-Hall (SRH) non-radiative recombination, which degrades chip performance. There are serval methods to reduce SRH non-radiative recombination. Thereamong, passivation is one of the most efficient methods. Accordingly, there is need for development of an optimized passivation layer of a micro light-emitting diode.

### RELATED ART DOCUMENTS

### Patent Documents

(Patent Documents 1) Korean Patent Application Publication No. 10-2019-0083736, “MICRO LED STRUCTURE AND MANUFACTURING METHOD OF THE SAME”

(Patent Documents 2) Korean Patent Application Publication No. 10-2019-0120299, “SEMICONDUCTOR DEVICE AND METHOD FOR MANUFACTURING SEMICONDUCTOR DEVICE”

(Patent Documents 3) US Patent Application Publication No. 2019/0115274, “BACKPLANE STRUCTURE AND PROCESS FOR MICRODRIVER AND MICRO LED”

(Patent Documents 4) Korean Patent Application Publication No. 10-2018-0013745, “DOPED ALD FILMS FOR SEMICONDUCTOR PATTERNING APPLICATIONS”

(Patent Documents 5) International Patent Application Publication No. 2019/089697, “REDUCTION IN LEAKAGE CURRENT AND INCREASE IN EFFICIENCY OF III-NITRIDE LEDS BY SIDEWALL PASSIVATION USING ATOMIC LAYER DEPOSITION”

### SUMMARY OF THE DISCLOSURE

Therefore, the present disclosure has been made in view of the above problems, and it is an object of the present disclosure to provide a micro light-emitting diode with a size of 100 μm or less which includes a double passivation layer capable of effectively passivating sidewalls of the micro light-emitting diode.

It is another object of the present disclosure to address leakage current characteristics of a micro light-emitting diode through application of a double passivation layer.

It is another object of the present disclosure to provide a micro light-emitting diode including a dielectric layer with a thickness of at least 200 nm, as a double passivation layer, using both the atomic layer deposition (ALD) method and a plasma-enhanced chemical vapor deposition (PECVD) method.

It is another object of the present disclosure to provide a micro light-emitting diode based on a double passivation layer which exhibits improved reliability without a change in current characteristics even if on/off is repeatedly performed.

It is another object of the present disclosure to provide a micro light-emitting diode that is based on a double passivation layer, and thus, is capable of effectively suppressing diffusion of atoms of a semiconductor layer into a dielectric layer at an interface between the semiconductor layer and the dielectric layer.

It is another object of the present disclosure to provide a micro light-emitting diode that is based on a double passivation layer, and thus, exhibits improved light extraction performance according to refractive index control.

It is another object of the present disclosure to provide a micro light-emitting diode that is based on a double passivation layer, and thus, is capable of suppressing sidewall damage-inducing current.

It is yet another object of the present disclosure to provide a micro light-emitting diode with a double passivation layer which is capable of effectively preventing Shockley-Read-Hall (SRH) non-radiative recombination by using both ALD of preciously controlling a layer thickness and PECVD of allowing rapid deposition compared to ALD.

In accordance with an aspect of the present disclosure, the above and other objects can be accomplished by the provision of a micro light-emitting diode, including: a first semiconductor layer; an intermediate layer; an active layer; an electron blocking layer; a second semiconductor layer; a first passivation layer; a second passivation layer; a first electrode; and a second electrode, wherein the first passivation layer is formed on sidewalls of the intermediate layer, the active layer, the electron blocking layer and the second semiconductor layer using an atomic layer deposition (ALD) method, the second passivation layer is formed on the first passivation layer using a plasma-enhanced chemical vapor deposition (PECVD) method, and the first and second passivation layers passivate the sidewalls.

The first passivation layer may be formed to a thickness of 20 nm to 50 nm using the ALD method.

The second passivation layer may be formed to a thickness of 250 nm to 280 nm using the PECVD method.

The first and second passivation layers may be formed of at least one dielectric material selected from Al₂O₃, SiO₂, SiNₓ, SiONe, ZrO₂ and HfO₂.

The second passivation layer may be formed of at least one dielectric material selected from SiO₂, SiNₓ, SiONe, ZrO₂ and HfO₂ when the first passivation layer is formed of Al₂O₃.

The micro light-emitting diode according to an embodiment of the present disclosure may further include a substrate, wherein the first semiconductor layer, the intermediate layer, the active layer, the electron blocking layer, and the second semiconductor layer are sequentially laminated on the substrate to form an epi-layer.

The epi-layer may recombine electrons and holes, supplied from the first semiconductor layer and the second semiconductor layer, in the active layer thereof to convert excess energy into light for output.

The first semiconductor layer may be a gallium nitride (GaN) semiconductor layer (n-GaN) doped with an n-type impurity and may supply electrons, the second semiconductor layer may be a gallium nitride (GaN) semiconductor layer (p-GaN) doped with a p-type impurity and may supply holes, and the active layer may recombine electrons and holes supplied from the first semiconductor layer and the second semiconductor layer to convert excess energy into light for output.

The first and second passivation layers may suppress diffusion of atoms, corresponding to the p-type impurity, from the sidewalls into a dielectric layer consisting of the first and second passivation layers.

In accordance with an embodiment of the present disclosure, the micro light-emitting diode may be formed to have any one of a lateral structure, a flip-chip structure and a vertical structure.

In accordance with another aspect of the present disclosure, there is provided a method of fabricating a micro light-emitting diode including a first semiconductor layer, an intermediate layer, an active layer, an electron blocking layer, a second semiconductor layer, a first passivation layer, a second passivation layer, a first electrode, and a second electrode, the method including: sequentially laminating the first semiconductor layer, the intermediate layer, the active layer, the electron blocking layer, and the second semiconductor layer, and then isolating a light-emitting diode chip including the first semiconductor layer, the intermediate layer, the active layer, the electron blocking layer, and the second semiconductor layer through ICP-RIE etching; forming the first passivation layer on sidewalls of the light-emitting diode chip using an atomic layer deposition (ALD) method; and forming the second passivation layer on the first passivation layer using a plasma-enhanced chemical vapor deposition (PECVD) method, wherein the first passivation layer and the second passivation layer passivate the sidewalls.

The forming of the first passivation layer may include forming the first passivation layer to a thickness of 20 nm to 50 nm using the ALD method.

The forming of the second passivation layer may include forming the second passivation layer to a thickness of 250 nm to 280 nm using the PECVD method.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1 to 3 illustrate a micro light-emitting diode according to an embodiment of the present disclosure;

FIG. 4A illustrates a method of fabricating a micro light-emitting diode according to an embodiment of the present disclosure;

FIG. 4B illustrates an LED chip isolation process of a method of fabricating a micro light-emitting diode according to an embodiment of the present disclosure;

FIGS. 5A to 6D illustrate operation characteristics of a micro light-emitting diode according to an embodiment of the present disclosure;

FIGS. 7A and 7B illustrates atom diffusion prevention characteristics of first and second passivation layers of the micro light-emitting diode according to an embodiment of the present disclosure;

FIG. 8 illustrates leakage current characteristics of a micro light-emitting diode according to existing technology;

FIG. 9 illustrates light-emitting characteristics dependent upon the sizes of micro light-emitting diodes;

FIGS. 10A and 10B illustrate current density-voltage characteristics of a micro light-emitting diode according to an embodiment of the present disclosure;

FIG. 11 illustrates light-emitting characteristics of a micro light-emitting diode according to an embodiment of the present disclosure;

FIG. 12 illustrates ideality factors dependent upon the sizes of micro light-emitting diodes according to an embodiment of the present disclosure;

FIGS. 13A and 13B illustrate external quantum efficiency (EQE) according to an embodiment of the present disclosure;

FIG. 14 illustrates a micro light-emitting diode having a flip-chip structure according to an embodiment of the present disclosure; and

FIG. 15 illustrates a micro light-emitting diode having a vertical structure according to an embodiment of the present disclosure.

### DETAILED DESCRIPTION OF THE DISCLOSURE

The present disclosure will now be described more fully with reference to the accompanying drawings, in which exemplary embodiments of the disclosure are shown.

This disclosure, however, should not be construed as limited to the exemplary embodiments and terms used in the exemplary embodiments, and should be understood as including various modifications, equivalents, and substituents of the exemplary embodiments.

Preferred embodiments of the present disclosure are now described more fully with reference to the accompanying drawings. In the description of embodiments of the present disclosure, certain detailed explanations of related known functions or constructions are omitted when it is deemed that they may unnecessarily obscure the essence of the disclosure.

In addition, the terms used in the specification are defined in consideration of functions used in the present disclosure, and can be changed according to the intent or conventionally used methods of clients, operators, and users. Accordingly, definitions of the terms should be understood on the basis of the entire description of the present specification.

In the drawings, like reference numerals in the drawings denote like elements.

As used herein, the singular forms “a,” “an” and “the” are intended to include the plural forms as well, unless context clearly indicates otherwise.

Expressions such as “A or B” and “at least one of A and/or B” should be understood to include all possible combinations of listed items.

Expressions such as “a first,” “the first,” “a second” and “the second” may qualify corresponding components irrespective of order or importance and may be only used to distinguish one component from another component without being limited to the corresponding components.

In the case in which a (e.g., first) component is referred as “(functionally or communicatively) connected” or “attached” to another (e.g., second) component, the first component may be directly connected to the second component or may be connected to the second component via another component (e.g., third component).

In the specification, the expression “ . . . configured to . . . (or set to)” may be used interchangeably, for example, with expressions, such as “ . . . suitable for . . . ,” “ . . . having ability to . . . ,” “ . . . modified to . . . ,” “ . . . manufactured to . . . ,” “ . . . enabling to . . . ,” or “ . . . designed to . . . ,” in the case of hardware or software depending upon situations.

In any situation, the expression “a device configured to . . . ” may refer to a device configured to operate “with another device or component.”

For examples, the expression “a processor configured (or set) to execute A, B, and C” may refer to a specific processor performing a corresponding operation (e.g., embedded processor), or a general-purpose processor (e.g., CPU or application processor) executing one or more software programs stored in a memory device to perform corresponding operations.

In addition, the expression “or” means “inclusive or” rather than “exclusive or”.

That is, unless otherwise mentioned or clearly inferred from context, the expression “x uses a or b” means any one of natural inclusive permutations.

The terms, such as ‘part’ or ‘unit’, etc., used below should be understood as a unit that processes at least one function or operation and that may be embodied in a hardware manner, a software manner, or a combination of the hardware manner and the software manner.

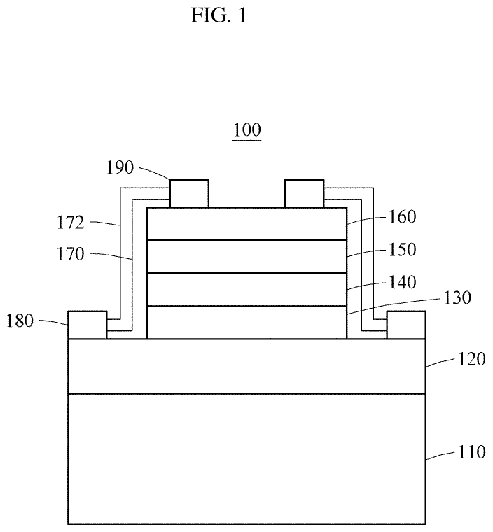

FIGS. 1 to 3 illustrate a micro light-emitting diode according to an embodiment of the present disclosure.

Particularly, FIG. 1 illustrates components of the micro light-emitting diode according to an embodiment of the present disclosure.

Referring to FIG. 1, a micro light-emitting diode 100 according to an embodiment of the present disclosure includes a first semiconductor layer 120, an intermediate layer 130, an active layer 140, an electron blocking layer 150, a second semiconductor layer 160, a first passivation layer 170, a second passivation layer 172, a first electrode 180 and a second electrode 190, and further includes a substrate 110.

In accordance with an embodiment of the present disclosure, the substrate 110 is included to allow growth of a gallium nitride (GaN) thin film, and is preferably a gallium nitride (GaN) single-crystal substrate. A substrate made of sapphire (Al₂O₃) or silicon carbide (SiC) that is relatively easy to obtain or inexpensive may be used instead of a gallium nitride (GaN) single-crystal substrate.

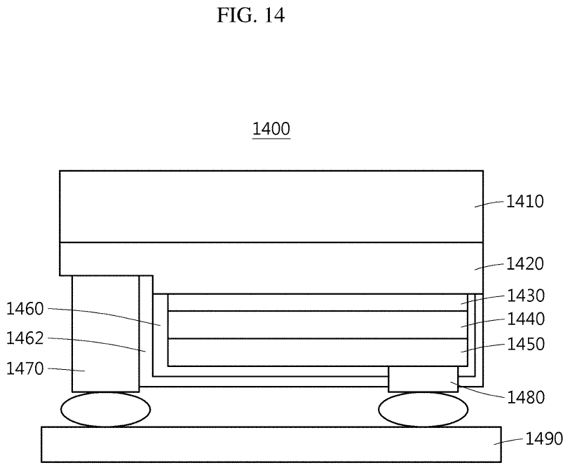

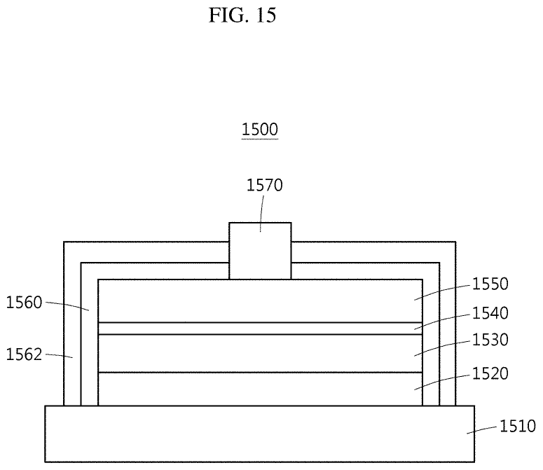

For example, the micro light-emitting diode illustrated in FIG. 1 may be a micro light-emitting diode having a lateral structure, FIG. 14 illustrates a micro light-emitting diode having a flip-chip structure, and FIG. 15 illustrates a micro light-emitting diode having a vertical structure.

In accordance with an embodiment of the present disclosure, the micro light-emitting diode may be formed to have any one of a lateral structure, a flip-chip structure and a vertical structure.

For example, the first semiconductor layer 120 may be a gallium nitride (GaN) semiconductor layer (n-GaN) doped with an n-type impurity and may supply electrons.

In accordance with an embodiment of the present disclosure, the first semiconductor layer 120 may include a gallium nitride (GaN) semiconductor layer (n-GaN) doped with Si.

For example, the first semiconductor layer 120 may serve to supply electrons to a light-emitting region, and may determine current spreading characteristics according to structure.

For example, an un-GaN layer may be additionally disposed under the first semiconductor layer 120, and a buffer layer may be further included under the un-GaN layer.

For example, the buffer layer may be provided to allow growth of gallium nitride (GaN), which is different from a material constituting a substate, on a substrate.

For example, the intermediate layer 130 is formed by mixing indium gallium nitride (InGaN) with gallium nitride (GaN), and is disposed between the first semiconductor layer 120 and the active layer 140.

For example, the intermediate layer 130 and the active layer 140 may be referred to as Multiple Quantum Well (MQW) layers, and may emit photons having a specific wavelength through a repeat structure of indium gallium nitride (InGaN) and gallium nitride (GaN) having different bandgaps. Here, light-emitting efficiency may be determined by the design of the intermediate layer 130.

In accordance with an embodiment of the present disclosure, the active layer 140 may recombine electrons and holes supplied from the first and second semiconductor layers 120 and 160 to convert excess energy into light for output.

For example, the active layer 140 may be formed by mixing indium gallium nitride (InGaN) and gallium nitride (GaN).

In accordance with an embodiment of the present disclosure, the active layer 140 may be disposed between the intermediate layer 130 and the electron blocking layer 150.

For example, in the electron blocking layer 150, an AlGaN layer may be formed of Mg.

In accordance with an embodiment of the present disclosure, the second semiconductor layer 160 may be a gallium nitride (GaN) semiconductor layer doped with a p-type impurity (p-GaN), and may supply holes.

For example, the second semiconductor layer 160 may be a gallium nitride (GaN) semiconductor layer doped with Mg (p-GaN).

In accordance with an embodiment of the present disclosure, the first passivation layer 170 may be formed on sidewalls of the intermediate layer 130, the active layer 140, the electron blocking layer 150 and the second semiconductor layer 160 using the atomic layer deposition (ALD) method.

For example, the first passivation layer 170 may be formed to a thickness of 20 nm to 50 nm using ALD.

In accordance with an embodiment of the present disclosure, the first passivation layer 170 may be made of at least one dielectric material selected from Al₂O₃, SiO₂, SiNₓ, SiONe, ZrO₂ and HfO₂ to form a dielectric layer.

For example, the first passivation layer 170 may passivate sidewalls.

In accordance with an embodiment of the present disclosure, the second passivation layer 172 may be formed on the first passivation layer 170 using a plasma-enhanced chemical vapor deposition (PECVD) method.

For example, the second passivation layer 172 may be formed to a thickness of 250 nm to 280 nm using PECVD.

Accordingly, the present disclosure may provide a micro light-emitting diode that includes a dielectric layer having a thickness of at least 200 nm, as a double passivation layer, using both ALD and PECVD.

In accordance with an embodiment of the present disclosure, the second passivation layer 172 may be made of at least one dielectric material selected from Al₂O₃, SiO₂, SiNₓ, SiONe, ZrO₂ and HfO₂ to form a dielectric layer.

For example, the second passivation layer 172 may be formed of at least one dielectric material selected from SiO₂, SiNₓ, SiONe, ZrO₂ and HfO₂ when the first passivation layer 170 is formed of Al₂O₃. That is, the first passivation layer 170 and the second passivation layer 172 may be formed of different dielectric materials.

In addition, the present disclosure may provide a micro light-emitting diode that includes a double passivation layer effectively passivating sidewalls of a micro light-emitting diode having a size of 100 μm or less.

In accordance with an embodiment of the present disclosure, the first and second passivation layers 170 and 172 may passivate sidewalls to effectively suppress leakage current of the micro light-emitting diode 100.

Accordingly, the present disclosure may address leakage current characteristics of a micro light-emitting diode through the double passivation layer.

In accordance with an embodiment of the present disclosure, the first and second passivation layers 170 and 172 may constitute of a double passivation layer and may be formed to a thickness of about 300 nm.

For example, the first and second passivation layers 170 and 172 may suppress diffusion of atoms, which correspond to a p-type impurity, into the dielectric layer constituting of the first and second passivation layers 170 and 172, from sidewalls.

For example, the first and second passivation layers 170 and 172 may prevent diffusion of Ga atoms.

For example, the first semiconductor layer 120, the intermediate layer 130, the active layer 140, the electron blocking layer 150, and the second semiconductor layer 160 may be sequentially laminated on the substrate 110 to form an epi-layer. The epi-layer may correspond to a light-emitting diode chip.

For example, the epi-layer may recombine electrons and holes, supplied from the first and second semiconductor layers 120 and 160, with the active layer 140 to convert excess energy into light for output.

In accordance with an embodiment of the present disclosure, the first electrode 180 may be formed on an n-ohmic contact layer that is formed on a region, the first semiconductor layer 130 of which is not etched.

For example, the second electrode 190 may be formed on a p-ohmic contact layer that is formed on a region, the second semiconductor layer 160 of which is not etched.

The micro light-emitting diode 100 according to an embodiment of the present disclosure may include at least one of a red micro light-emitting diode, a blue micro light-emitting diode and a green micro light-emitting diode.

For example, the micro light-emitting diode 100, which is a micro light-emitting diode based on a group III-V compound, may implement red, blue, and green according to the bandgap energy of a group III-V compound.

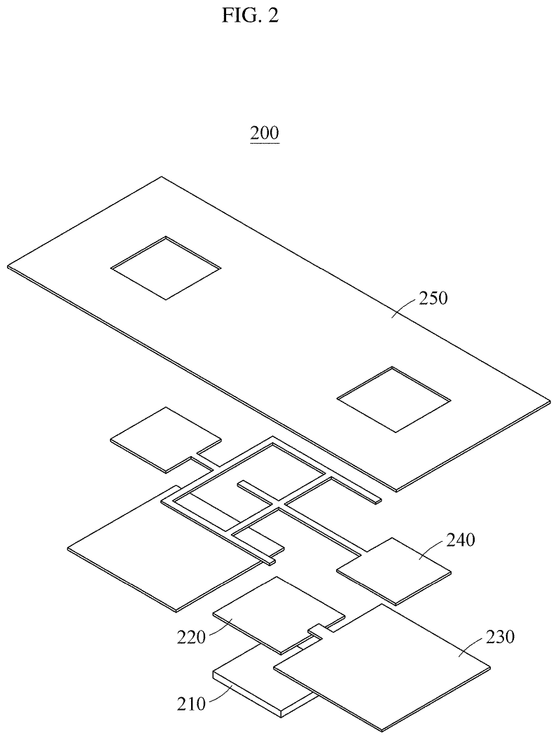

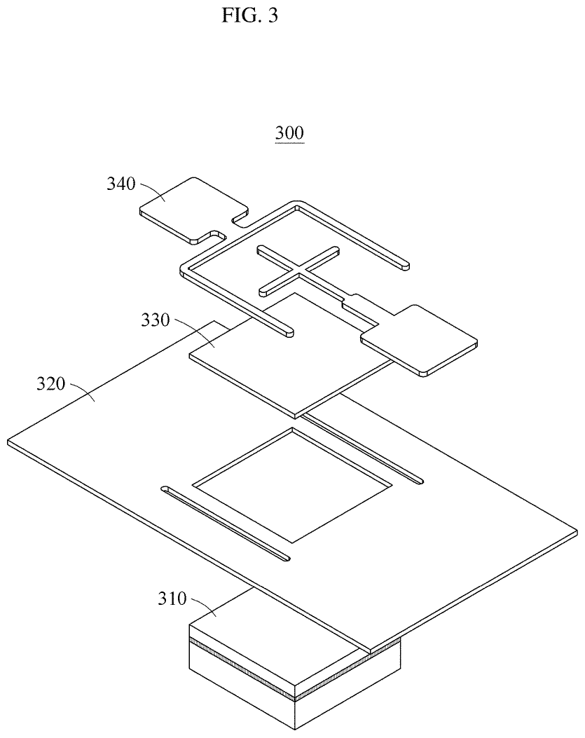

FIGS. 2 and 3 illustrate three-dimensional configurations of the micro light-emitting diode according to an embodiment of the present disclosure.

Referring to FIG. 2, a micro light-emitting diode 200 may include an epi-layer 210, a second electrode 220, a first passivation layer 230, a first electrode 240 and a second passivation layer 250.

For example, the first passivation layer 230 may be formed using ALD, and the second passivation layer 250 may be formed using PECVD.

The micro light-emitting diode 200 according to the present disclosure may be formed by sequentially forming the epi-layer 210, forming a p-ohmic contact layer for forming the second electrode 220 on the epi-layer 210, forming the first passivation layer 230 using ALD, forming an n-ohmic contact layer for forming the first electrode 240, and forming the second passivation layer 250 using PECVD.

Referring to FIG. 3, a micro light-emitting diode 300 may include a light-emitting diode chip 310, a dielectric passivation layer 320, an electrode 330, and an electrode pad layer 340.

For example, the light-emitting diode chip 310 may correspond to the epi-layer 210, and the dielectric passivation layer 320 may correspond to a combined structure of the first and second passivation layers 230 and 250.

In accordance with an embodiment of the present disclosure, the light-emitting diode chip 310 may be isolated through an ICP-RIE etching process, and the angle of the light-emitting diode chip 310 may be adjusted according to an ICP-RIE etching process.

For example, the dielectric passivation layer 320 may be formed using ALD and PECVD.

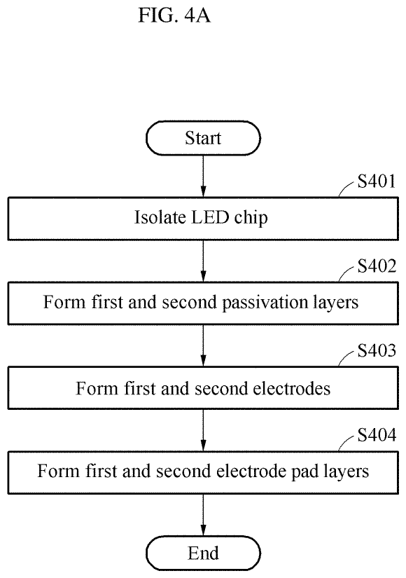

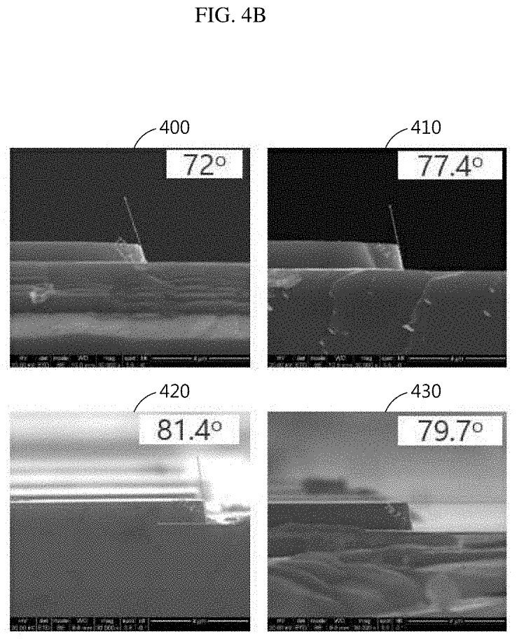

FIG. 4A illustrates a method of fabricating a micro light-emitting diode according to an embodiment of the present disclosure.

Referring to FIG. 4A, an LED chip is isolated in S401 of the method of fabricating a micro light-emitting diode according to an embodiment of the present disclosure.

That is, the method of fabricating a micro light-emitting diode is characterized by sequentially laminating a first semiconductor layer, an intermediate layer, an active layer, an electron blocking layer, and a second semiconductor layer, and then ICP-RIE etching a light-emitting diode chip including the first semiconductor layer, the intermediate layer, the active layer, the electron blocking layer, and the second semiconductor layer to isolate an LED chip. For example, the LED chip may refer to a light-emitting diode chip.

In S402 of the method of fabricating a micro light-emitting diode according to an embodiment of the present disclosure, the first and second passivation layers are formed.

That is, in the method of fabricating a micro light-emitting diode, the first passivation layer may be formed on sidewalls of the light-emitting diode chip using ALD, and the second passivation layer may be formed on the first passivation layer using PECVD.

In S403 of the method of fabricating a micro light-emitting diode according to an embodiment of the present disclosure, the first and second electrodes are formed.

That is, in the method of fabricating a micro light-emitting diode, the first electrode is formed from the first semiconductor layer, and the second electrode is formed from the second semiconductor layer.

In S404 of the method of fabricating a micro light-emitting diode according to an embodiment of the present disclosure, first and second electrode pad layers are formed.

That is, in the method of fabricating a micro light-emitting diode, the first and second electrode pad layers may be formed to cover the first and second electrodes.

Accordingly, the present disclosure provides a micro light-emitting diode that is based on the double passivation layer, and thus, is capable of improving light extraction performance of according to refractive index control.

FIG. 4B illustrates an LED chip isolation process of a method of fabricating a micro light-emitting diode according to an embodiment of the present disclosure.

Referring to FIG. 4B, the method of fabricating a micro light-emitting diode according to an embodiment of the present disclosure uses an ICP-RIE process to isolate an LED chip. By controlling the type, amount, and power of gas used in the ICP-RIE process, the angle of formation of the light-emitting diode device may be controlled and leakage characteristics may be changed.

An image 400, an image 410, an image 420 and an image 430 illustrate examples of angle adjustment according to an ICP-RIE process. A PR mask was used in the image 400 and the image 410, and a SiO₂ mask was used in the image 420 and the image 430.

The image 400 and the image 410 exhibit smaller angles than the image 420 and the image 430. This is because the SiO₂ mask is harder than the photoresist (PR) mask. Accordingly, for efficient passivation, a PR mask-based ICP-RIE process may be more advantageous in terms of leakage current block by passivation.

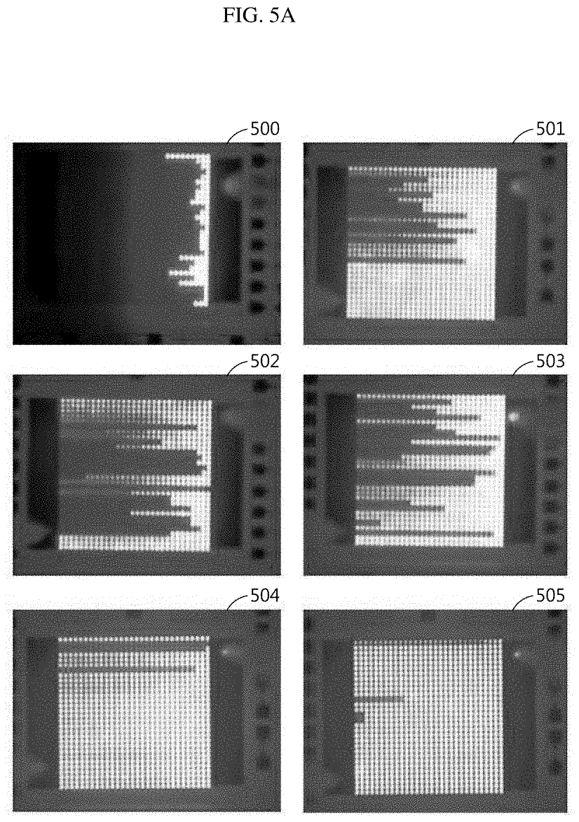

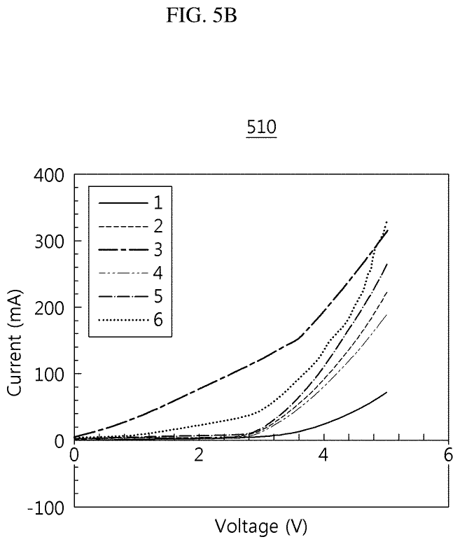

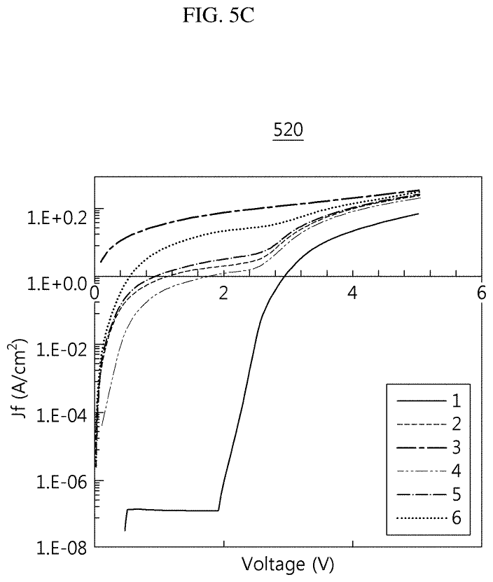

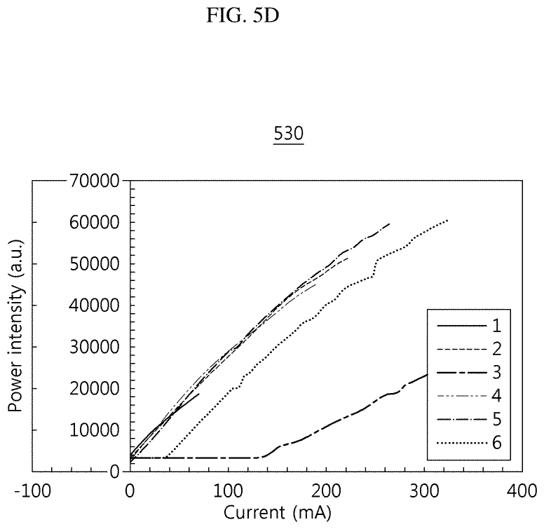

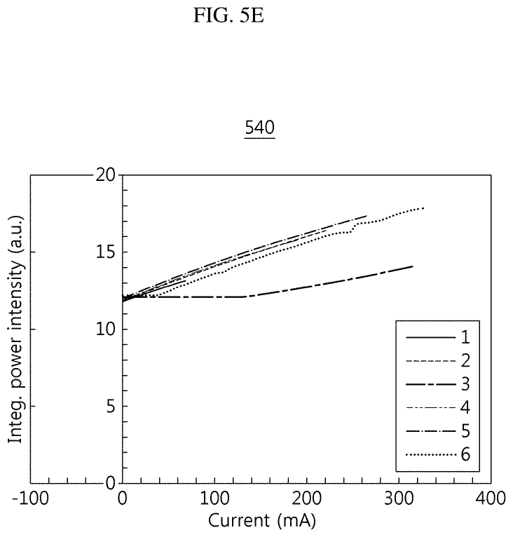

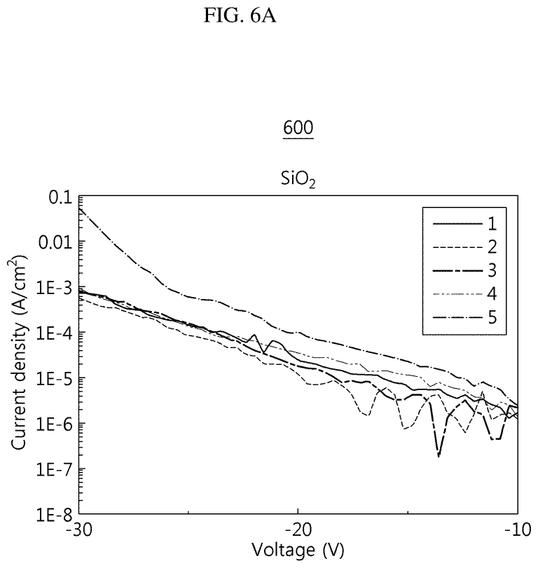

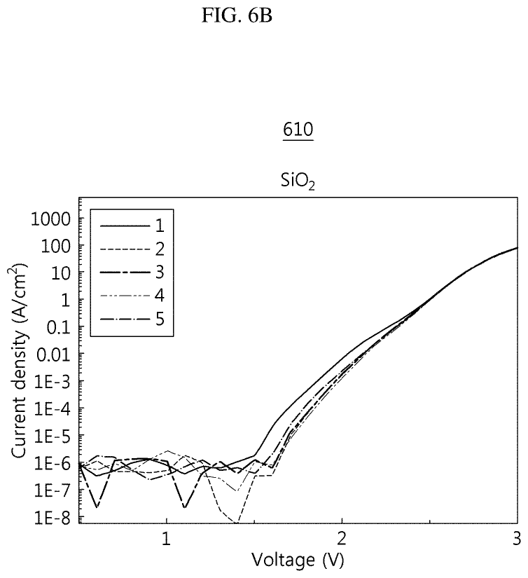

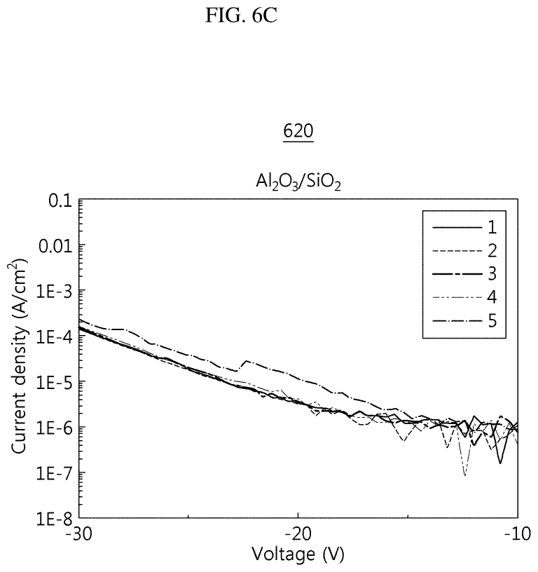

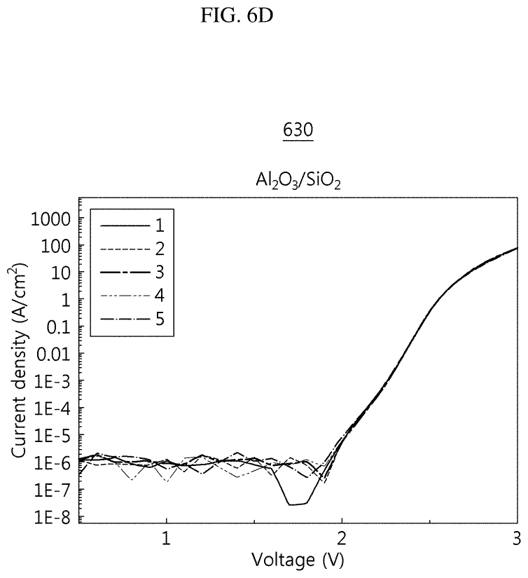

FIGS. 5A to 6D illustrate operation characteristics of a micro light-emitting diode according to an embodiment of the present disclosure.

Particularly, FIGS. 5A to 5E illustrate optical power changes according to the operation of six micro light-emitting diode samples illustrated in FIG. 5A.

FIG. 5A illustrates images of a first sample 500, a second sample 501, a third sample 502, a fourth sample 503, a fifth sample 504 and a sixth sample 505.

The first sample 500 to the sixth sample 505 include different numbers of micro light-emitting diodes in a turned-on state. The number of turned-on micro light-emitting diodes is the smallest in the first sample 500, but is the largest in the sixth sample 505.

FIGS. 5B to 5E illustrate changes in optical characteristics of the first to sixth samples 500 to 505.

Referring to graph 510 of FIG. 5B and graph 520 of FIG. 5C, it can be confirmed that current versus voltage of the third sample 502 is higher than that of the sixth sample 505.

In addition, it can be confirmed that, compared to the first sample 500, the other samples have higher current versus voltage.

Meanwhile, graph 530 of FIG. 5D and graph 540 of FIG. 5E illustrate power intensity to current.

Examining graph 530 of FIG. 5D and graph 540 of FIG. 5E, the first sample 500 exhibits high power intensity to current, compared to other samples.

In addition, referring to FIG. 5A, it can be confirmed that the first sample 500 exhibits relatively high power intensity to current although a relatively small number of light-emitting diodes is turned-on in the first sample 500. This indicates that it may be very important to reduce leakage current through passivation. In addition, it can be confirmed that the first sample 500 including the passivation layer exhibits relatively reduced leakage current, compared to other samples excluding the passivation layer.

FIGS. 6A to 6D illustrate repeated current density versus voltage measurement results of a micro light-emitting diode including a single passivation layer and a micro light-emitting diode including a double passivation layer.

Graph 600 of FIG. 6A and graph 610 of FIG. 6B illustrate repeated current density versus voltage measurement results of micro light-emitting diodes including a single passivation layer, and graph 620 of FIG. 6C and graph 630 of FIG. 6D illustrate repeated current density versus voltage measurement results of micro light-emitting diodes including a double passivation layer.

Regarding graphs 600 and 610, a slight variation is observed in the repeated current density versus voltage measurement results. However, regarding graphs 620 and 630, a current characteristic variation is not large in the repeated current density versus voltage measurement results.

Accordingly, the present disclosure provide a micro light-emitting diode that is based on the double passivation layer, and thus, has improved reliability without a change in current characteristics even if on/off is repeatedly performed.

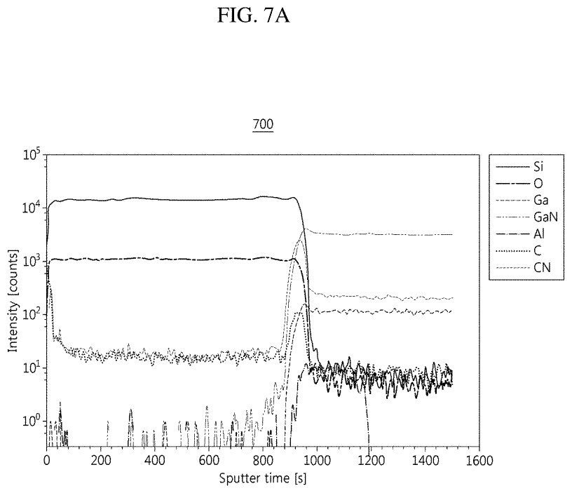

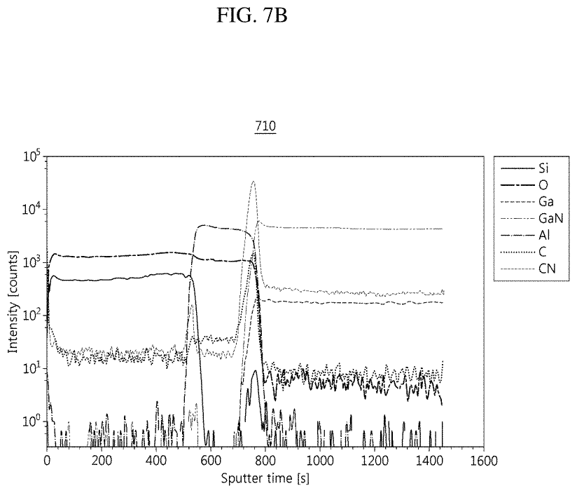

FIGS. 7A and 7B illustrate atom diffusion prevention characteristics of first and second passivation layers of the micro light-emitting diode according to an embodiment of the present disclosure.

FIG. 7A illustrates atom diffusion data of a micro light-emitting diode including a single passivation layer, and FIG. 7B illustrates atom diffusion data of a micro light-emitting diode including a double passivation layer according to an embodiment of the present disclosure.

Referring to graph 700 of FIG. 7A and graph 710 of FIG. 7B, in the case of graph 700, Ga atom at an interface between a GaN layer and a dielectric layer is diffused into the dielectric layer, thereby deteriorating the properties of the dielectric layer. In the case of graph 710, diffusion of Ga atom is effectively blocked by the double passivation layer, thereby preventing property deterioration of the dielectric layer.

That is, the present disclosure provides a micro light-emitting diode that is based on a double passivation layer, and thus, is capable of effectively suppressing diffusion of atoms of the semiconductor layer, which are present at an interface between the semiconductor layer and the dielectric layer, into the dielectric layer.

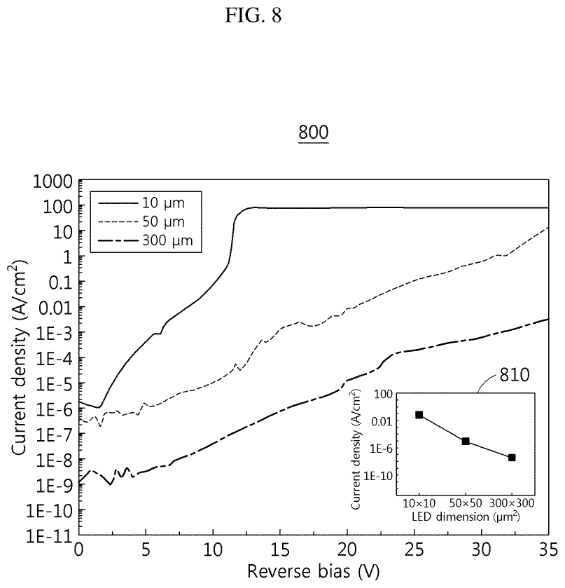

FIG. 8 illustrates leakage current characteristics of a micro light-emitting diode according to existing technology.

FIG. 8 illustrates leakage current characteristics of a micro light-emitting diode including a single passivation layer according to existing technology.

Graph 800 of FIG. 8 illustrates current density-reverse bias characteristics of light-emitting diodes with different sizes which include a Al₂O₃ passivation layer with a thickness of 50 nm formed using ALD.

Meanwhile, graph 810 illustrates current densities of a micro light-emitting diode at −10 V as functions of chip sizes.

Graph 800 illustrates current density-voltage characteristics of light-emitting diodes with different sizes that include a Al₂O₃ passivation layer with a thickness of 50 nm formed using ALD under reverse bias conditions. From the graph, it can be confirmed that current density increases as the size of light-emitting diode is reduced and reverse bias increases. In particular, in the case of a micro light-emitting diode with a size of 10 μm, current density may rapidly increase when a reverse bias exceeds −3V.

Accordingly, a micro light-emitting diode having a reduced chip size requires application of a double passivation layer to efficiently passivate leakage current of sidewalls thereof.

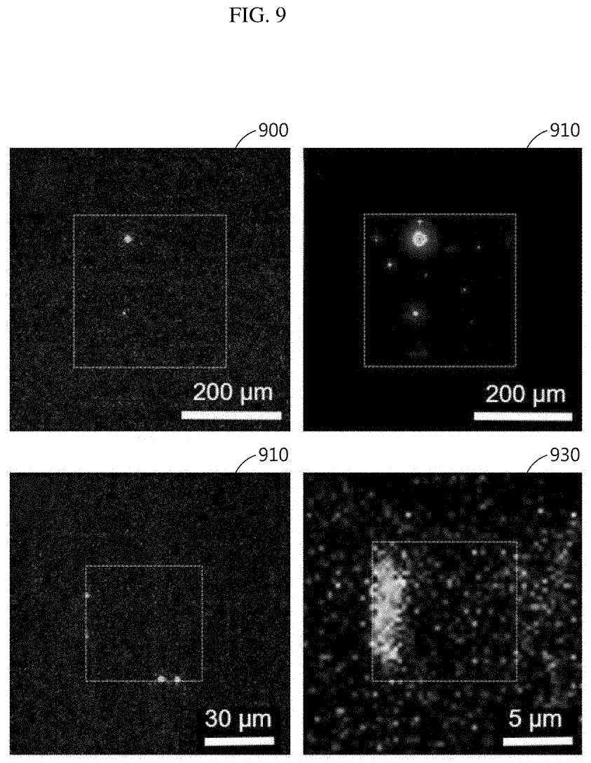

FIG. 9 illustrates light-emitting characteristics dependent upon the sizes of micro light-emitting diodes.

FIG. 9 illustrates light-emitting characteristics dependent upon sizes of micro light-emitting diodes including a single passivation layer.

Referring to FIG. 9, images 900 and 910 illustrate light-emitting images of an LED with a size of 300 μm. Particularly, the images were respectively photographed at −10 V and −20 V, and it can be confirmed that the number and intensity of bright spots increase with increasing reverse voltage. Meanwhile, images 920 and 930 respectively correspond to micro light-emitting diodes with sizes of 50 μm and 10 μm, respectively, and illustrate light-emitting spots located at sidewall regions.

That is, images 900 to 930 show that SRH non-radiative recombination cannot be suppressed when a single passivation layer is included or the thickness of a passivation layer does not exceed a predetermined standard (about 200 nm).

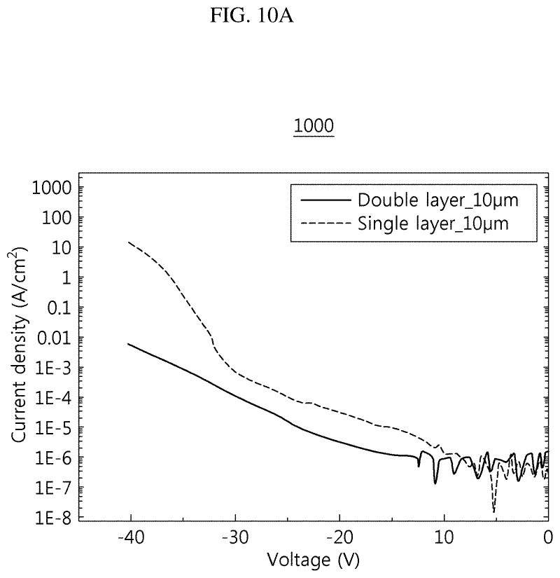

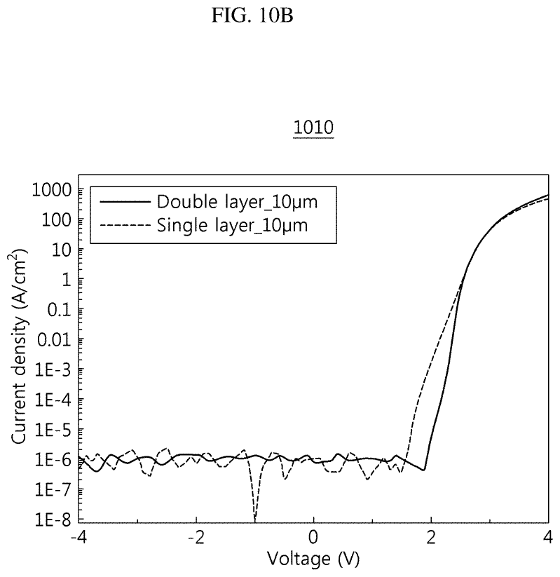

FIGS. 10A and 10B illustrate current density-voltage characteristics of a micro light-emitting diode according to an embodiment of the present disclosure.

FIGS. 10A and 10B illustrate current density-voltage characteristics of micro light-emitting diodes with a size of 10 μm respectively including single and double passivation layers.

Referring to graph 1000, two micro light-emitting diodes having different passivation layers exhibit almost the same leakage current at less than −10V. Referring to graph 1010, the single passivation layer exhibits higher leakage current at a voltage exceeding −10V, and the double passivation layer more efficiently passivates sidewalls than the single layer.

In addition, as shown in graph 1000, the double passivation layer exhibits improved forward direction characteristics in a voltage region of 1.5V to 2.5V, which indicates that the double passivation layer has an effectively passivated parasitic current path.

FIG. 11 illustrates light-emitting characteristics of a micro light-emitting diode according to an embodiment of the present disclosure.

FIG. 11 illustrates light-emitting images of the micro light-emitting diodes respectively having the single passivation layer and the double passivation layer described with reference to FIG. 10.

Referring to FIG. 11, image 1100 illustrates the micro light-emitting diode having the double passivation layer, and image 1110 illustrates the micro light-emitting diode having the single passivation layer.

Comparing image 1100 to image 1110, brighter spots (emission spots) are observed in most sidewall regions of image 1110, which indicate the double passivation layer effectively suppresses surface recombination and SRH non-radiative recombination. Here, bright spots (emission spots) may be related to leakage current due to defects.

The micro light-emitting diode according to an embodiment of the present disclosure includes a double passivation layer, thereby exhibiting satisfactory passivation. This may be a complementary result of PECVD providing an excellent sidewall range; and ALD providing an excellent step (edge) range.

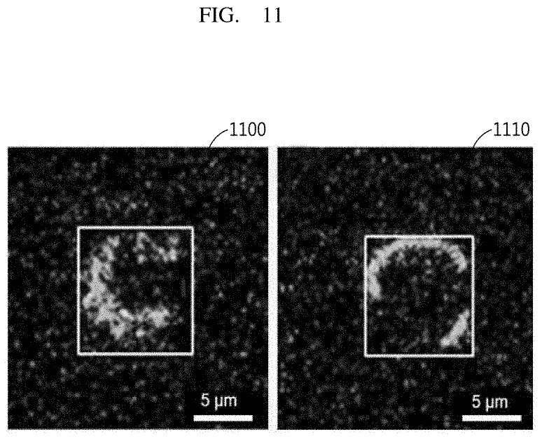

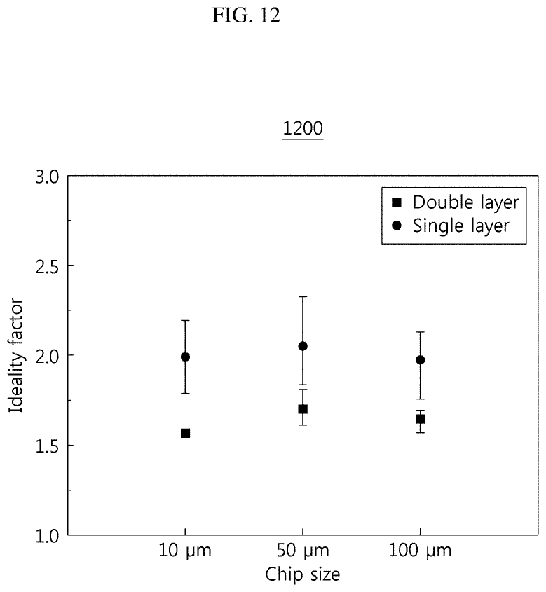

FIG. 12 illustrates ideality factors dependent upon the sizes of micro light-emitting diodes according to an embodiment of the present disclosure.

FIG. 12 illustrates ideality factors of micro light-emitting diodes with different sizes which respectively include single and double passivation layers.

The micro light-emitting diode including the single passivation layer exhibits an ideality factor of about 2.0, which indicates that SRH non-radiative recombination according to a defect level can be responsible for leakage behavior.

The sample including the double passivation layer exhibits an ideality factor of less than 2.0, which indicates relaxation of SRH non-radiative recombination.

In accordance with an embodiment of the present disclosure, an ideality factor may be calculated according to Equation 1 below.

$$n = \frac{q}{KT} {( \frac{\partial ln I}{\partial V} )}^{- 1} \qquad [ Equation 1 ]$$

In Equation 1, n denotes an ideality factor, q denotes a basic charge, k denotes the Boltzmann constant, and T denote a temperature.

An ideality factor of 2.0 is known to be related to SRH recombination according to a defect level, and an ideality factor of greater than 2.0 is known to be due to defect-assisted tunneling. Accordingly, it can be confirmed that the double passivation layer effectively suppresses surface recombination and SRH non-radiative recombination.

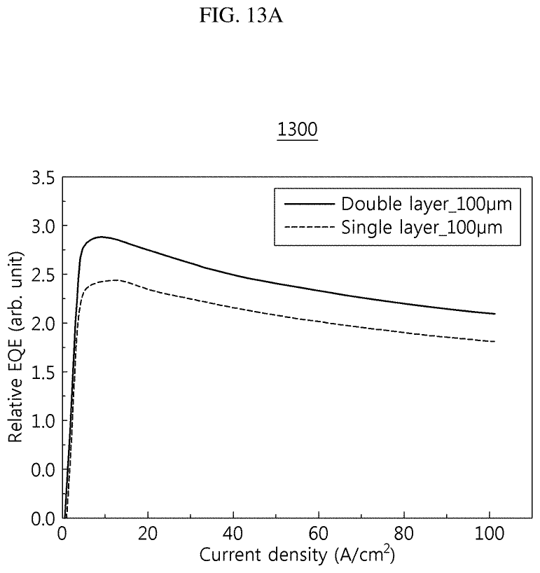

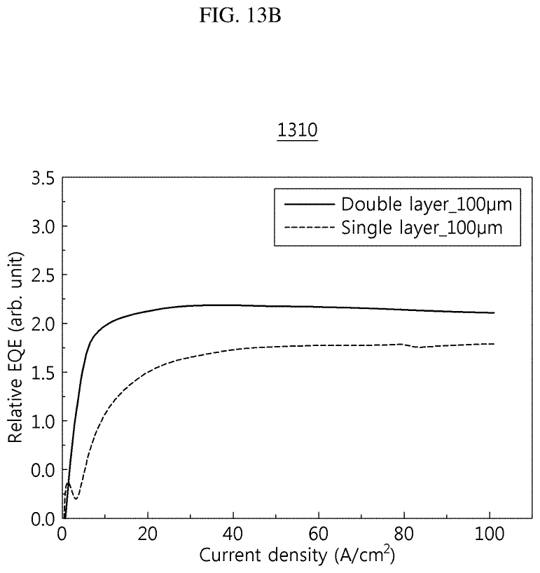

FIGS. 13A and 13B illustrate external quantum efficiency (EQE) according to an embodiment of the present disclosure.

Graph 1300 of FIG. 13A and graph 1310 of FIG. 13B illustrate external quantum efficiency (EQE) of micro light-emitting diodes respectively including single and double passivation layers.

Graph 1300 illustrates that EQE peaks of micro light-emitting diodes with a size of 100 μm respectively including double and single passivation layers are respectively observed at current densities of 13 and 14 A/cm².

Graph 1310 illustrates that EQE peaks of micro light-emitting diodes with a size of 10 μm are respectively observed at 35 and 79 A/cm².

In addition, referring to graph 1300, the micro light-emitting diode with a size of 100 μm including the double passivation layer exhibits an EQE peak 19.3% higher than that of the micro light-emitting diode including the single passivation layer. On the other hand, referring to graph 1310, the micro light-emitting diode with a size of 10 μm including the double passivation layer exhibits an EQE peak 22.3% higher than that of the micro light-emitting diode including the single passivation layer.

As shown in the above data, a smaller micro light-emitting diode suffers more from SRH non-radiative recombination due to a relatively large ratio of sidewall to surface, compared to a larger micro light-emitting diode.

For example, sidewall circumference to surface area ratios of the micro light-emitting diodes respectively having sizes of 100 μm and 10 μm may be respectively estimated to be 0.04 and 0.4. This indicates that a smaller micro light-emitting diode, than a larger micro light-emitting diode, requires more efficient passivation.

In particular, the micro light-emitting diode having a size of 10 μm have two characteristics. First, regardless of passivation conditions, the micro light-emitting diode with a size of 10 μm exhibits low efficiency reduction, compared to the micro light-emitting diode with a size of 100 μm. This may be related to an initial low EQE at low current density due to non-radiative recombination.

In addition, the characteristics of the micro light-emitting diode having a size of 10 μm may be caused by uniform current and heat diffusion, and may exhibit an EQE peak at a lower current density than in the case including the single passivation layer.

Accordingly, the present disclosure provides a micro light-emitting diode that is based on a double passivation layer, and thus, is capable of suppressing sidewall damage-inducing current.

In addition, the present disclosure provides a micro light-emitting diode with a double passivation layer which is capable of effectively preventing Shockley-Read-Hall (SRH) non-radiative recombination by using both ALD of preciously controlling a layer thickness and PECVD of allowing rapid deposition compared to ALD.

FIG. 14 illustrates a micro light-emitting diode having a flip-chip structure according to an embodiment of the present disclosure.

Referring to FIG. 14, a micro light-emitting diode 1400 according to an embodiment of the present disclosure may include a substrate 1410, a first semiconductor layer 1420, an intermediate layer 1430, an active layer 1440, a second semiconductor layer 1450, a first passivation layer 1460, a second passivation layer 1462, a first electrode 1470 and a second electrode 1480. The micro light-emitting diode 1400 may be a micro light-emitting diode with a flip-chip structure of being flip-bonded to a submount.

In accordance with an embodiment of the present disclosure, the first semiconductor layer 1420, the intermediate layer 1430, the active layer 1440, the second semiconductor layer 1450, the first passivation layer 1460, the second passivation layer 1462, the first electrode 1470 and the second electrode 1480 may perform the same roles as the substrate 110, the first semiconductor layer 120, the intermediate layer 130, the active layer 140, the second semiconductor layer 160, the first passivation layer 170, the second passivation layer 172, the first electrode 180 and the second electrode 190 described in FIG. 1.

For example, the micro light-emitting diode 1400 and the micro light-emitting diode 100 have only structure differences, and the sidewall passivation role of the first and second passivation layers are the same in both the micro light-emitting diode 1400 and the micro light-emitting diode 100.

For example, the micro light-emitting diode 1400 may be fabricated through a bonding process of turning a lateral chip and bonding the same to a PCB substrate, etc., and the first passivation layer 1460 and the second passivation layer 1462 function to suppress leakage and to insulate against the first electrode 1470 and the second electrode 1480.

In addition, since a flip-chip requires a bonding process, a passivation layer thereof should have excellent mechanical characteristics.

FIG. 15 illustrates a micro light-emitting diode having a vertical structure according to an embodiment of the present disclosure.

Referring to FIG. 15, the micro light-emitting diode 1500 according to an embodiment of the present disclosure includes a substrate 1510, a first semiconductor layer 1520, an intermediate layer 1530, an active layer 1540, a second semiconductor layer 1550, a first passivation layer 1560, a second passivation layer 1562 and an electrode 1570.

For example, the substrate 1510 may be made of a metal to serve as the first electrode 180, and the electrode 1570 may serve as the second electrode 190.

For example, the first semiconductor layer 1520, the intermediate layer 1530, the active layer 1540, the second semiconductor layer 1550, the first passivation layer 1560, the second passivation layer 1562 and the electrode 1570 may perform the same roles as the first semiconductor layer 120, the intermediate layer 130, the active layer 140, the second semiconductor layer 160, the first passivation layer 170, the second passivation layer 172 and the second electrode 190 described in FIG. 1.

For example, the most important characteristic of a vertical chip is that both a top surface and a bottom surface have conductivity. For example, a sapphire substrate may be separated using a laser lift-off, but the present disclosure is not limited thereto.

In addition, in the case of both a flip-chip structure and a vertical structure, when heat and pressure are applied in a bonding process, and thus, a passivation layer is destroyed, a light-emitting diode may not work. Accordingly, a light-emitting diode should be fabricated to a thickness of at least 300 nm, and a multilayer insulating film may improve mechanical characteristics.

As apparent from the above description, the present disclosure can provide a micro light-emitting diode with a size of 100 μm or less which includes a double passivation layer capable of effectively passivating sidewalls of the micro light-emitting diode.

The present disclosure can address leakage current characteristics of a micro light-emitting diode through application of a double passivation layer.

The present disclosure can provide a micro light-emitting diode including a dielectric layer with a thickness of at least 200 nm, as a double passivation layer, using both the atomic layer deposition (ALD) method and a plasma-enhanced chemical vapor deposition (PECVD) method.

The present disclosure can provide a micro light-emitting diode based on a double passivation layer which exhibits improved reliability without a change in current characteristics even if on/off is repeatedly performed.

The present disclosure can provide a micro light-emitting diode that is based on a double passivation layer, and thus, is capable of effectively suppressing diffusion of atoms of a semiconductor layer into a dielectric layer at an interface between the semiconductor layer and the dielectric layer.

The present disclosure can provide a micro light-emitting diode that is based on a double passivation layer, and thus, exhibits improved light extraction performance according to refractive index control.

The present disclosure can provide a micro light-emitting diode that is based on a double passivation layer, and thus, is capable of suppressing sidewall damage-inducing current.

The present disclosure can provide a micro light-emitting diode with a double passivation layer which is capable of effectively preventing Shockley-Read-Hall (SRH) non-radiative recombination by using both ALD of preciously controlling a layer thickness and PECVD of allowing rapid deposition compared to ALD.

In the aforementioned embodiments, constituents of the present disclosure were expressed in a singular or plural form depending upon embodiments thereof.

However, the singular or plural expressions should be understood to be suitably selected depending upon a suggested situation for convenience of description, and the aforementioned embodiments should be understood not to be limited to the disclosed singular or plural forms. In other words, it should be understood that plural constituents may be a singular constituent or a singular constituent may be plural constituents.

While the embodiments of the present disclosure have been described, those skilled in the art will appreciate that many modifications and changes can be made to the present disclosure without departing from the spirit and essential characteristics of the present disclosure.

Therefore, it should be understood that there is no intent to limit the disclosure to the embodiments disclosed, rather, the disclosure is to cover all modifications, equivalents, and alternatives falling within the spirit and scope of the disclosure as defined by the claims.

[Description of Symbols]

| | |
|---|---|
| 100: micro light-emitting diode | 110: substrate |
| 120: first semiconductor layer | 130: intermediate layer |
| 140: active layer | 150: electron block layer |
| 160: second semiconductor layer | 170: first passivation layer |
| 172: second passivation layer | 180: first electrode |
| 190: second electrode | |

What is claimed is:

1. A micro light-emitting diode, comprising:
a first semiconductor layer;
an intermediate layer;
an active layer;
an electron blocking layer;
a second semiconductor layer;
a first passivation layer;
a second passivation layer;
a first electrode; and
a second electrode,
wherein the first passivation layer is formed on sidewalls of the intermediate layer, the active layer, the electron blocking layer and the second semiconductor layer using an atomic layer deposition (ALD) method,
the second passivation layer is formed on the first passivation layer using a plasma-enhanced chemical vapor deposition (PECVD) method, and
the first and second passivation layers passivate the sidewalls.

2. The micro light-emitting diode according to claim 1, wherein the first passivation layer is formed to a thickness of 20 nm to 50 nm using the ALD method.

3. The micro light-emitting diode according to claim 1, wherein the second passivation layer is formed to a thickness of 250 nm to 280 nm using the PECVD method.

4. The micro light-emitting diode according to claim 1, wherein the first and second passivation layers are formed of at least one dielectric material selected from Al₂O₃, SiO₂, SiNₓ, SiONe, ZrO₂ and HfO₂.

5. The micro light-emitting diode according to claim 4, wherein the second passivation layer is formed of at least one dielectric material selected from SiO₂, SiNₓ, SiONe, ZrO₂ and HfO₂ when the first passivation layer is formed of Al₂O₃.

6. The micro light-emitting diode according to claim 1, further comprising a substrate,
wherein the first semiconductor layer, the intermediate layer, the active layer, the electron blocking layer, and the second semiconductor layer are sequentially laminated on the substrate to form an epi-layer.

7. The micro light-emitting diode according to claim 6, wherein the epi-layer recombines electrons and holes, supplied from the first semiconductor layer and the second semiconductor layer, in the active layer thereof to convert excess energy into light for output.

8. The micro light-emitting diode according to claim 1, wherein the first semiconductor layer is a gallium nitride (GaN) semiconductor layer (n-GaN) doped with an n-type impurity and supplies electrons,
the second semiconductor layer is a gallium nitride (GaN) semiconductor layer (p-GaN) doped with a p-type impurity and supplies holes, and
the active layer recombines electrons and holes supplied from the first semiconductor layer and the second semiconductor layer to convert excess energy into light for output.

9. The micro light-emitting diode according to claim 8, wherein the first and second passivation layers suppress diffusion of atoms, corresponding to the p-type impurity, from the sidewalls into a dielectric layer consisting of the first and second passivation layers.

10. The micro light-emitting diode according to claim 1, wherein the micro light-emitting diode is formed to have any one of a lateral structure, a flip-chip structure and a vertical structure.

11. A method of fabricating a micro light-emitting diode comprising a first semiconductor layer, an intermediate layer, an active layer, an electron blocking layer, a second semiconductor layer, a first passivation layer, a second passivation layer, a first electrode, and a second electrode, the method comprising:
sequentially laminating the first semiconductor layer, the intermediate layer, the active layer, the electron blocking layer, and the second semiconductor layer, and then isolating a light-emitting diode chip comprising the first semiconductor layer, the intermediate layer, the active layer, the electron blocking layer, and the second semiconductor layer through ICP-RIE etching;
forming the first passivation layer on sidewalls of the light-emitting diode chip using an atomic layer deposition (ALD) method; and
forming the second passivation layer on the first passivation layer using a plasma-enhanced chemical vapor deposition (PECVD) method,
wherein the first passivation layer and the second passivation layer passivate the sidewalls.

12. The method according to claim 11, wherein the forming of the first passivation layer comprises forming the first passivation layer to a thickness of 20 nm to 50 nm using the ALD method.

13. The method according to claim 11, wherein the forming of the second passivation layer comprises forming the second passivation layer to a thickness of 250 nm to 280 nm using the PECVD method.
